(19) United States
(12) Patent Application Publication
(10) Pub. No.: US 2015/0208506 A1
(43) Pub. Date: Jul. 23, 2015

(54) A PRINTED CIRCUIT BOARD ARRANGEMENT AND A METHOD FOR FORMING ELECTRICAL CONNECTION AT A PRINTED CIRCUIT BOARD

(71) Applicants: Igor Perez-Uria, Jarfalla (SE); Per Ferm, Taby (SE); Benny Gustafson, Spanga (SE)

(72) Inventors: Igor Perez-Uria, Jarfalla (SE); Per Ferm, Taby (SE); Benny Gustafson, Spanga (SE)

(73) Assignee: TELEFONAKTIEBOLAGET L M ERICSSON (PUBL), Stockholm (SE)

(21) Appl. No.: 14/420,681

(22) PCT Filed: Aug. 10, 2012
(86) PCT No.: PCT/SE2012/050868

§ 371 Date: Feb. 10, 2015

(51) Int. Cl. H05K 1/14; H05K 3/10; H05K 3/42; H05K 1/11

(52) U.S. Cl. CPC H05K 1/144; H05K 1/115; H05K 3/10; H05K 3/42; H05K 2201/09572; H05K 2201/10234

(57) ABSTRACT

The present invention relates to a printed circuit board arrangement and a method for forming an electrical connection at a printed circuit board. The printed circuit board arrangement comprises a printed circuit board having an electrical connection electrically connecting a first conductive layer on a first side of the printed circuit board and a second conductive layer on a second side of the printed circuit board. The electrical connection comprises a passage extending from an opening in one of the sides of the printed circuit board through the printed circuit board between the first and second layers. Electrically conducting material is formed on the walls of the passage and forms a first path electrically connecting the first conductive layer with the second conductive layer. At least one first ball is enclosed by the passage and forms part of a second electrical path between the first and second conductive layers of the printed circuit board, said second electrical path having a lower resistance than the first path.

### TECHNICAL FIELD

The present invention relates to printed circuit boards. More particularly, the invention relates to a printed circuit board arrangement and a method for forming electrical connection at a printed circuit board.

### BACKGROUND

Power conversion technology is heading towards higher current density and power while at the same time minimizing. Accordingly, interconnection channels between host board and devices are slimmed to fit miniaturization product demands.

The tendency towards cost effective and tightly denser electronic packaging demands flexibility with regard to component placement on a board (e.g dual side), current distribution and optimal thermal integrity from semiconductor, copper traces, solder joints down to host board.

Harsh application environments (outdoor enclosures or application with limited forced convection) demands optimal thermal design integrity/minimal losses in the power distribution.

U.S. Pat. No. 6,913,187 describes a method of providing thermal vias in a printed circuit board. One or more holes are provided in the printed circuit board. A metal ball is inserted to each hole and subjected to pressure such as to deform the ball and tightly fixating the resultant slug against the wall of the hole. The deformed ball or slug fixed in the hole functions to conduct heat and/or electricity between a metallized top side and bottom side of the printed circuit board.

Electronic devices, such as integrated circuit chips, are commonly attached to a substrate or printed circuit card with ball connectors using a ball grid array (BGA) connection technique. Using the ball grid array usually involves attachment of an array of balls located on the underside of an electronic device to a corresponding array of contact pads located on a surface of a substrate, using individual solder joints.

It is known in the art to use copper plated and/or polymer-plated and/or lead free solder spheres in for example ball grid arrays or 3D packaging applications. Solder copper balls placed between host board and device's signal/power source provide an effective/low ohmic interconnection channel.

U.S. Pat. No. 6,252,779 discloses a method for joining electronic devices such as integrated circuits to vias in a substrate. The method involves providing a substrate have a conductive opening therein and securely positioning an electrically conductive member within the conductive opening to plug the conductive opening.

### SUMMARY

One object of the invention is to improve the prior art with respect to current transfer between layers of printed circuit boards.

This has in one option been achieved by means of a printed circuit board arrangement. The printed circuit board arrangement comprises a printed circuit board having a first side and a second side and an electrical connection electrically connecting a first conductive layer and a second conductive layer of the printed circuit board. The electrical connection comprises a passage extending from an opening in one of the sides of the printed circuit board through the printed circuit board between the first and second layers. An electrically conducting material is formed on the walls of the passage. The electrically conducting material forms a first path electrically connecting the first conductive layer with the second conductive layer. At least one first ball is enclosed by the passage. The at least one first ball is electrically conducting and has a diameter which is equal to or smaller than the length and diameter of the passage. The at least one first ball forms part of a second electrical path between the first and second conductive layers of the printed circuit board. The second electrical path has a lower resistance than the first path.

One advantage with the present invention is that the electrical connection provides for a reinforced current transfer between layers of the printed circuit board. The currents transferred between layers of a printed circuit board can be increased with maintained or increased package size. Existing limitations in the currents which can be transferred by means of the walls of the passage between the conductive layers of the printed circuit board is remedied by means of the second path passing the at least one first ball.

The electrical connection between the layers is low ohmic. This provides for low power losses and consequently the need for dissipating heat from the connection is less than in conventional connections between layers. Thus, the electrical transfer between layers can be achieved while keeping stress due to temperature limits within acceptable levels. The use of the at least one first ball for the second path is cost effective. The cost for producing the balls having high conductivity is low. The mounting of the electrical connection comprising the at least one first ball is of low complexity and consequently cost effective.

In one option, the at least one first ball has an electrical conductivity a higher than 3×10⁷ S/m at 20°. The high conductivity of the at least one first ball secures the low resistance of the second path. The first ball comprises in one example copper or a copper alloy.

In one option, the electrically conductive material formed on the walls is in low ohmic or low resistance contact with the surface of the at least one first ball. Thereby an electrical path between the wall and at least one first ball forms part of the second electrical path between the first and second conductive layers of the printed circuit board.

In one option, the passage is filled or partially filled with solder. The solder provides for the low ohmic or low resistance contact between the wall and the at least one first ball.

In one option, the printed circuit board arrangement comprises a second ball centered against an opening of the passage at the first and/or second side. Each second ball has a diameter larger than the diameter of the passage and is electrically conducting. Thereby the second ball can be used for communication of data and or for power transfer between the printed circuit board and other electrical equipment electrically connected to the second ball. Further, the second ball can also be used for dissipating heat from the printed circuit board. Further, the second ball closes the opening to the passage. In one example, each second ball is soldered to its associated surface. Thus, the opening to the passage is closed by means of soldering.

In one option, at least one electrical device is electrically connected to the printed circuit board by means of the second ball(s). The other electrical device may be a main board or motherboard. The second ball may be centered in an opening formed in the other electrical device so as to provide electrical contact with the other electrical device.

In one option, one method for forming an electrical connection at a printed circuit board comprises the following steps:
providing at least one passage in the printed circuit board extending from an opening in one side of the printed circuit board through the printed circuit board between a first conductive layer and a second conductive layer of the printed circuit board,
providing the walls of the passage with an electrically conducting material so as to electrically connect the first and second conducting layers of the printed circuit board by means of a first electrical path,
providing at least one electrically conducting first ball having a diameter which is equal to or smaller than the length and diameter of the passage, and
filling the at least one first ball in the passage, thereby providing a second electrical path for electrically connecting the first and second conducting layers, wherein the second electrical path has a lower resistance than the first path.

In one option, wherein a plurality of first balls are provided, the step of filling the passage comprises filling the passage with the plurality of first balls so that the passage completely encloses the first balls. Thereby the first balls form a substantial part of the second path.

In one option, the method further comprises the steps of providing an electrically conducting second ball having a diameter larger than the diameter of the passage and self centering the second ball against an opening of the passage at the first side of the printed circuit board.

In one option, the passage is at least partly filled with solder.

In one option, the method further comprises the steps of providing another electrically conducting second ball having a diameter larger than the diameter of the passage and self centering that second ball against the passage opening at the second side of the printed circuit board. Each second ball may be fixed to the associated surface for example by means of solder.

Adjacent balls, first and/or second balls, may be fixed to each other for example by means of solder or etching.

In one option, the method comprises further a step of providing electrical contact between the second ball and an electrical conductor of another electrical device. The providing of the electrical contact may comprise centering the second ball in an opening formed in the electrical device.

In one option, the printed circuit board is heated.

### BRIEF DESCRIPTION OF THE DRAWINGS

FIG. 1 illustrates schematically a side view of a cross section of a part of a printed circuit board according to one example.

FIG. 2 illustrates schematically a side view of a cross section of a part of a printed circuit board according to another example.

FIG. 3 illustrates schematically a side view of an electrical connection for use in a printed circuit board.

FIG. 4 illustrates schematically a side view of a cross section of a part of a printed circuit board according to yet another example.

FIG. 5 is a flowchart illustrating one example of a method for forming an electrical connection at a printed circuit board.

FIG. 6 is a flowchart illustrating another example of a method for forming an electrical connection at a printed circuit board.

### DETAILED DESCRIPTION

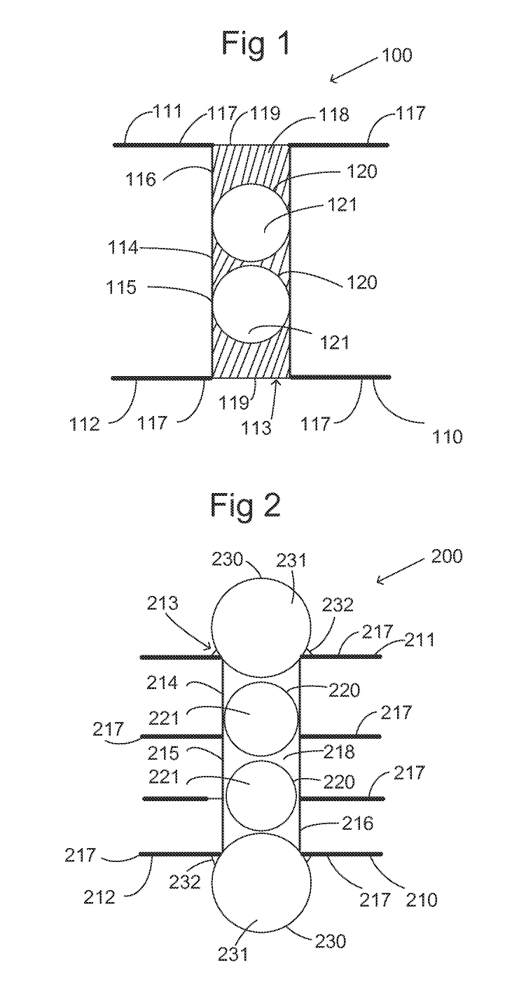

In FIG. 1 a printed circuit board arrangement 100 comprises a printed circuit board 110. The printed circuit board 110 has a first side 111 and a second side 112. An electrical connection 113 electrically connects a first conductive layer 117 and a second conductive layer 117 of the printed circuit board.

The respective first and second layers are arranged to transfer power and/or communication signals. The respective first and second layers may also be arranged to transfer heat. The layers may be formed as conductive patterns having one or a plurality of conductive lines and/or conductive areas. The first and second layers are in one example metalized. The metalized first and second layers comprise in one example copper or a copper alloy.

In this particular illustrated example, the first and second layers are formed on the first and second sides, respectively.

The electrical connection 113 comprises a passage 116 extending from an opening 119 in one of the sides 111, 112 of the printed circuit board 110 through the printed circuit board between the first and second layers. In one example the passage is formed as a straight or oblique cylinder. In another example, the passage is shaped as a truncated cone. The cylinder/cone may have a circular cross section. In one example, the passage extends perpendicularly in relation to the printed circuit board sides. In one example (not shown) the passage 116 only partly penetrates the printed circuit board (a blind via).

In this particular illustrated example, the passage 116 extends between an opening in each respective side of the printed circuit board forming a through hole.

Electrically conducting material 114 is formed on the wall 115 of the passage. This electrically conducting material forms a first path electrically connecting the first conductive layer 117 with the second conductive layer 117. In one example, the wall of the passage is completely or partly plated with the electrically conductive material. The thickness of the conductive material formed on the walls of the passage sets the limit for the current level which it is possible to transfer by means of the first electrical path between the first and second layers. In one example, the conductive material formed on the wall comprise in one example copper or a copper alloy.

The passage 116 encloses at least one first ball 120. The at least one first ball 120 is electrically conducting. The at least one first ball forms part of a second electrical path between the first and second conductive layers of the printed circuit board. The second electrical path has a lower resistance than the first path. In one example, the first ball has an electrical conductivity a higher than 3×10⁷ S/m at 20° C. The at least one first ball may comprise copper or a copper alloy. The electrical conductivity is then characteristically 93-96% IACS. In one example, the at least one first ball is solid. A surface 121 of the first ball(s) is in one example plated with plating material. The plating may be present so as to avoid corrosion. The plating material comprises in one example tin, silver, nickel, or gold or a combination of some of these metals. In one example, the surface of the first balls treated with other solderability protectant, e.g. OSP.

The at least one first ball has a size which is equal to or smaller than the length and diameter of the passage. First balls of different shapes may be used. For example, at least some of the first balls are in one example sphere shaped. Other first ball(s) may be of other shapes such as cylinder shaped. At least some of the first ball(s) may have one or a plurality of grooves and/or notches and/or channels formed therein. Thereby outgassing, ventilation and/or wetting can be improved. The first balls may be selected so as to harmonize with a desired current and/or load. For example, the size, shape and/or electrical conductivity of the at least one ball can be selected so as to harmonize against a desired current and/or load in the electrical connection. If more than one first ball is used, first balls of different sizes, shapes and/or electrical conductivity can be used so as to harmonize with the desired current/load. If more than one first ball is used, the first ball(s) 120 are in low ohmic or low resistance contact with each other. In one example, the first balls are in direct physical contact with each other.

The first ball(s) 120 is in low ohmic or low resistance contact with the first and second layers, as discussed above. Further, the first ball is in one example in low ohmic or low resistance contact with the electrically conductive material formed on the wall 115. The passage may be filled or partially filled with solder 118 so as to achieve this low ohmic/resistance contact between first ball(s) and the wall. In one example the solder material comprises tin (Sn) or a tin alloy.

In FIG. 2, a printed circuit board arrangement 200 comprises a printed circuit board 210, as discussed in relation to FIG. 1. The printed circuit board 210 has a first side 211 and a second side 212. An electrical connection 213 electrically connects at least a first conductive layer 217 and a second conductive layer 217 of the printed circuit board. In the illustrated example, layers are formed on the surface of each side of the printed circuit board. Further, layers are also formed integrated within the printed circuit board. At least one of the layers integrated within the surface board extend into electrical contact with the passage wall.

As discussed in relation to FIG. 1, the electrical connection 213 comprises a passage 216 extending from an opening in one of the sides of the printed circuit board 210 through the printed circuit board between the at least first and second layers.

In this particular illustrated example, the passage 216 extends between an opening in each respective side of the printed circuit board forming a go-through hole.

As discussed in relation to FIG. 1, electrically conducting material 214 is formed on the wall 215 of the passage. This electrically conducting material forms a first path electrically connecting the at least first and second conductive layers 217. The passage 216 encloses at least one first ball 220, as discussed in relation to FIG. 1.

A second ball 230 is centered against an opening of the passage 216 at the first and/or second side. In this particular illustrated a second ball 230 is centered against an opening of the passage at both sides of the printed circuit board. Each second ball has a diameter larger than the size of the opening to the passage.

Each second ball 230 is electrically conducting. The at least one second ball may form part of the second electrical path between the at least first and second conductive layers of the printed circuit board, as discussed in relation to FIG. 1. In one example, the each second ball has an electrical conductivity a higher than 3×10⁷ S/m at 20° C. Each second ball may comprise copper or a copper alloy. The electrical conductivity is then characteristically 93-96 IACS. In one example, each second ball is solid. A surface 221 of each second ball is in one example plated with plating material. The plating may be present so as to avoid corrosion. The plating material comprises in one example tin, silver, nickel, palladium or gold or a combination of some of these metals. In one example, the surface of the first balls treated with other solderability protectant, e.g. OSP. Each second ball(s) may have one or a plurality of grooves and/or notches and/or channels formed therein. Thereby outgassing, ventilation and/or wetting can be secured. Each second ball 230 is in one example soldered 232 to its associated surface 211 212 of the printed circuit board.

The printed circuit board arrangement 200 provides for an efficient thermo transport from the printed circuit board and especially the electrical connection 213 to the environment by means of the second ball(s).

Further, the second ball(s) 230 form part of a third electrical path between any of the layers 217 and other equipment electrically connected to the second ball(s). The third electrical path is arranged to transfer electrical power and/or electrical signals.

In FIG. 4, a printed circuit board arrangement 400 comprises a printed circuit board 410. As discussed in relation to FIGS. 1 and 2, the printed circuit board 410 has a first side 411 and a second side 412 and an electrical connection 413 electrically connecting a first conductive layer 417 and a second conductive layer 417 of the printed circuit board. The electrical connection 413 comprises a passage 416 extending from an opening 419 in one of the sides of the printed circuit board 410 through the printed circuit board between the first and second layers.

As discussed in relation to FIGS. 1 and 2, electrically conducting material 414 is formed on the wall 415 of the passage. This electrically conducting material forms a first path electrically connecting the first and second conductive layers 417. The passage 416 encloses a plurality of balls 220, as discussed in relation to FIGS. 1 and 2.

As discussed in relation to FIG. 2, a second ball 430 is centered against an opening in the passage 416 at the second side 412. The second ball 430 has a diameter larger than the size of the opening to the passage. The second ball 430 is electrically conducting. It may form part of the second electrical path between the first and second conductive layers of the printed circuit board, as discussed in relation to FIGS. 1 and 2. A surface 421 of the second ball is in one example plated with solderable plating material.

Further, the second ball(s) 430 form part of a third electrical path between any of the layers 417 and another electrical device 440 electrically connected to the second ball. The third electrical path is arranged to transfer electrical power and/or electrical signals between the printed circuit board and the other electrical device 440. The third electrical path is in one example also arranged to transfer heat between the printed circuit board and the other electrical device 440. The other electrical device 440 is for example a main board or a motherboard. In the illustrated example, the second ball 430 is centered in an opening 436 formed in the other electrical device so as to provide electrical contact with the other electrical device 440.

This arrangement wherein a plurality of printed circuit boards and/or electrical devices can be mounted on each other by means of the second ball centered in an opening of the respective printed circuit board/electrical device have many advantages. For example, it provides for a predetermined and consistent standoff height between the printed circuit boards and/or electrical devices. Further, it provides for design flexibility as the arrangement allows for selecting the size of the second ball relatively freely as long as the second balls does not fit into the passage 416. Therefore the size of the second ball can be selected to fit with a desired standoff height.

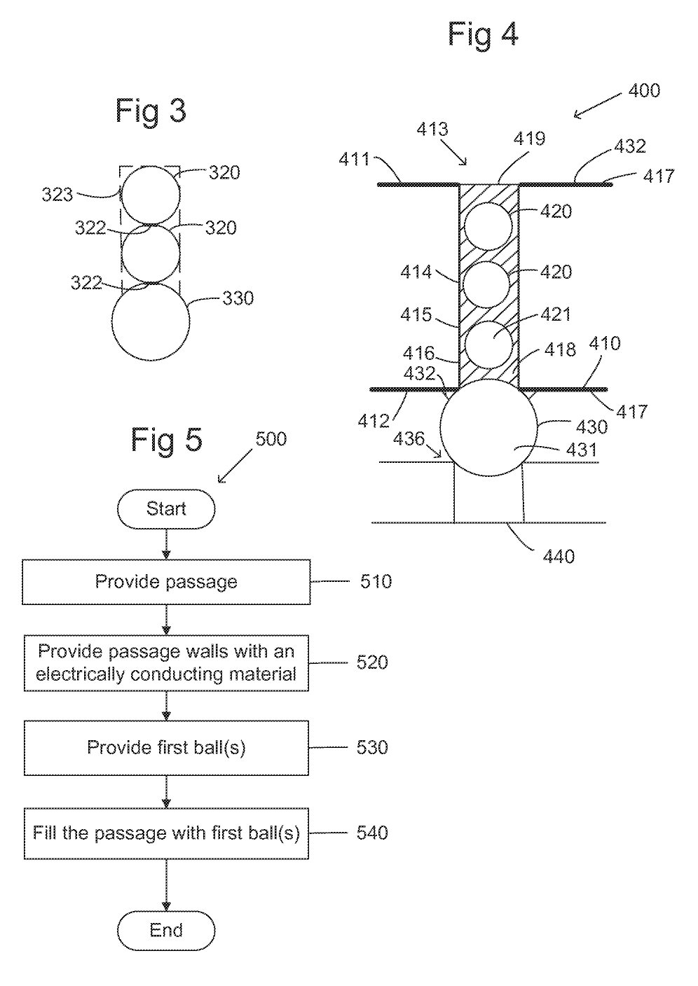

In FIG. 3, a plurality of first balls 320 and optionally also a second ball 330 forms a tower of balls for insertion in the passage. Adjacent balls are fixed to each other in fixing points 322 for example by means of etching. Alternatively, the balls are fixed to each other by means of soldering to a carrier 323.

In FIG. 5, a method 500 for forming an electrical connection at a printed circuit board comprises the following steps.

In a first step, at least one passage is provided 510 in the printed circuit board extending from an opening in one side of the printed circuit board through the printed circuit board between a first conductive layer and a second conductive layer of the printed circuit board.

Thereafter, the walls of the passage is provided 520 with an electrically conducting material so as to electrically connect the first and second conducting layers of the printed circuit board by means of a first electrical path.

Then, at least one electrically conducting first ball is provided 530. The at least one first ball has a diameter which is equal to or smaller than the length and diameter of the passage.

Thereafter, the at least one first ball is filled 540 in the passage. Thereby, a second electrical path is provided for electrically connecting the first and second conducting layers, wherein the second electrical path has a lower resistance than the first path.

In one example, wherein a plurality of first balls are provided 530, the step of filling 540 the passage comprises filling the passage with the plurality of first balls so that the passage completely encloses the first balls.

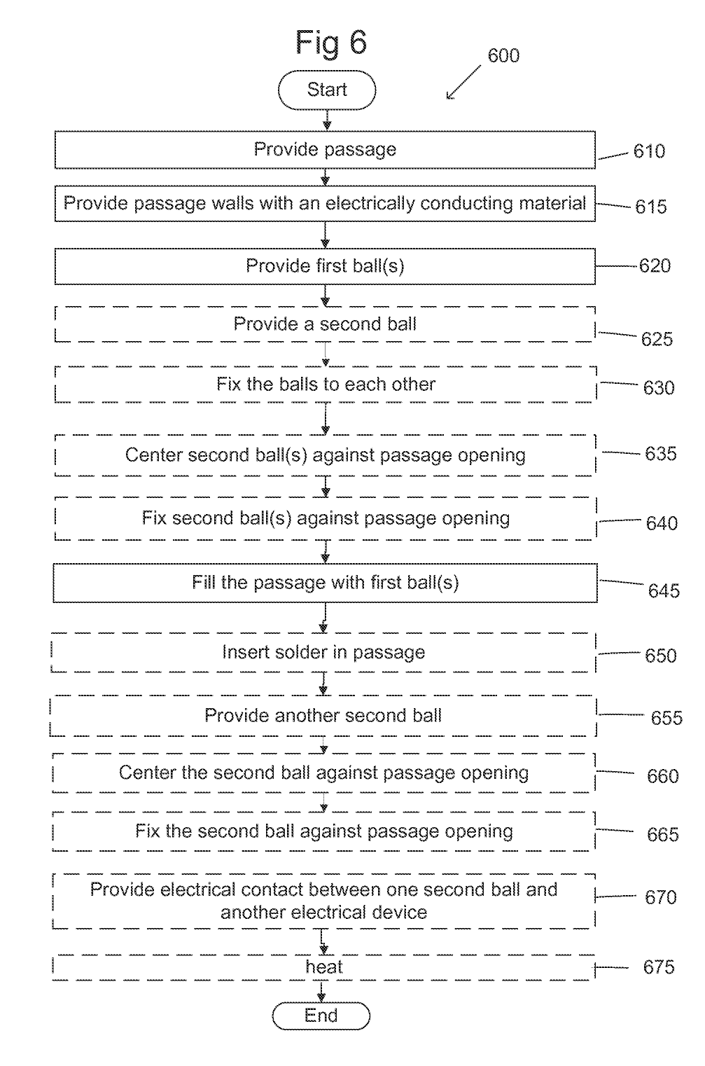

In FIG. 6, a method 600 for forming an electrical connection at a printed circuit board comprises the above described steps of providing 610 at least one passage in the printed circuit board, providing 615 the walls of the passage with an electrically conducting material, providing 620 at least one electrically conducting first ball and filling 645 the at least one first ball in the passage.

The method 600 comprises in one example also the steps of providing 625 an electrically conducting second ball having a diameter larger than the diameter of the passage and centering or self centering 635 the second ball against an opening of the passage at the first side of the printed circuit board. The second ball may be fixed 640 to the surface of the printed circuit board for example by means of soldering.

In one example the first balls and optionally also the second ball are fixed 630 to each other before being filled 645 in the passage. In one example, the first balls and optionally also the second ball are etched to each other into a tower of balls of a desired design. Alternatively, the first balls and optionally also the second ball are soldered to a carrier so as to provide to the tower of balls having a desired design.

After the passage has been filled with the first balls, solder may be inserted 650 in the passage so as to at least partly fill the passage with the solder.

In the example illustrated in FIG. 6, the second ball is first centered 635 and fixed 640 to the surface of the printed circuit board from one side of the printed circuit board, whereupon the first ball(s) are filled from the other, non-plugged side of the printed circuit board. However, the method steps may be performed in another order. In one example, wherein the opening to the passage is plugged in any permanent or temporary way from one side of the printed circuit board, the first balls may be filled 645 in the passage from the non-plugged side, the solder may inserted 650 in the passage from the non-plugged side and thereafter the second ball is centered 635 and fixed 640 against the passage opening from the non-plugged side of the printed circuit board.

When the passage is filled, it is on one example closed by providing 655 another electrically conducting second ball having a diameter larger than the diameter of the passage and self centering 660 that second ball against the passage opening at the second side of the printed circuit board. Also this other second ball may be fixed 665 to its associated surface for example by means of soldering.

If at least one second ball has been mounted to the printed circuit board the method may further comprise a step of providing 670 electrical contact between the second ball and an electrical conductor of another electrical device. The providing 670 of the electrical contact may comprise centering the second ball in an opening formed in the electrical device.

In one example, the method comprises a one or a plurality of heating steps 675.

1. A printed circuit board arrangement comprising:
a printed circuit board having an electrical connection electrically connecting a first conductive layer on a first side of the printed circuit board and a second conductive layer on a second side of the printed circuit board, wherein the electrical connection comprises:
a passage extending from an opening in one of the sides of the printed circuit board through the printed circuit board between the first and second conductive layers,
electrically conducting material formed on the walls of the passage, said electrically conducting material forming a first path electrically connecting the first conductive layer with the second conductive layer and
a first ball enclosed by the passage, said first ball being electrically conducting and having a diameter which is equal to or smaller than the length and diameter of the passage, wherein the first ball forms part of a second electrical path between the first and second conductive layers of the printed circuit board, said second electrical path having a lower resistance than the first path.

2. The printed circuit board arrangement according to claim 1, wherein the first ball has an electrical conductivity a higher than 3×10⁷ S/m at 20° C.

3. The printed circuit board arrangement according to claim 1, wherein the first ball comprises copper or a copper alloy.

4. The printed circuit board arrangement according to claim 1, wherein the electrically conductive material formed on the walls is in low ohmic contact with the surface of the first ball.

5. The printed circuit board arrangement according to claim 1, wherein the passage is filled or partially filled with solder.

6. The printed circuit board arrangement according to claim 1, comprising an electrically conducting second ball centered against an opening of the passage at the first or second side, the second ball having a diameter larger than the diameter of the passage.

7. The printed circuit board arrangement according to claim 6, wherein the second ball is soldered to an associated surface.

8. The printed circuit board arrangement according to claim 6, wherein another electrical device is electrically connected to the printed circuit board by means of the second ball.

9. The printed circuit board arrangement according to claim 8, wherein the other electrical device is a main board or motherboard.

10. The printed circuit board arrangement according to claim 8, wherein the second ball is centered in an opening formed in the other electrical device so as to provide electrical contact with the other electrical device.

11. A method for forming an electrical connection at a printed circuit board, the method comprising:
providing at least one passage in the printed circuit board extending from an opening in one side of the printed circuit board through the printed circuit board between a first conductive layer and a second conductive layer of the printed circuit board,
providing the walls of the passage with an electrically conducting material so as to electrically connect the first and second conductive layers of the printed circuit board by means of a first electrical path,
providing an electrically conducting first ball having a diameter which is equal to or smaller than the length and diameter of the passage, and
filling the passage with the first ball, thereby providing a second electrical path for electrically connecting the first and second conducting layers, wherein the second electrical path has a lower resistance than the first path.

12. The method according to claim 11, wherein a plurality of first balls having a diameter which is equal to or smaller than the length and diameter of the passage are provided, the step of filling the passage comprises filling the passage with the plurality of first balls so that the passage completely encloses the first balls.

13. The method according to claim 11, comprising the steps of providing an electrically conducting second ball having a diameter larger than the diameter of the passage and self centering the second ball against an opening of the passage at the first side of the printed circuit board.

14. The method according to claim 11, further comprising a step of at least partly filling the passage with solder.

15. The method according to claim 13, further comprising the steps of providing another electrically conducting second ball having a diameter larger than the diameter of the passage and self centering that second ball against the passage opening at the second side of the printed circuit board.

16. The method according to claim 13, wherein each second ball is fixed to an associated surface.

17. The method according to claim 16, wherein each second ball is fixed to the associated surface by means of solder.

18. The method according to claim 12, wherein adjacent ones of the first balls are fixed to each other by means of solder or etching.

19. The method according to claim 13, further comprising a step of providing electrical contact between the second ball and an electrical conductor of another electrical device.

20. The method according to claim 19 wherein the providing of the electrical contact comprises centering the second ball in an opening formed in the electrical device.

21. The method according to claim 11, wherein the printed circuit board is heated.
